(19) United States
(12) Patent Application Publication
(10) Pub. No.: US 2020/0003802 A1
(43) Pub. Date: Jan. 2, 2020

(54) TESTING SOCKET AND TESTING APPARATUS

(71) Applicant: Powertech Technology Inc., Hsinchu County (TW)

(72) Inventors: Ping-Che Lee, Hsinchu County (TW); Ying-Tang Chao, Hsinchu County (TW)

(73) Assignee: Powertech Technology Inc., Hsinchu County (TW)

(21) Appl. No.: 16/024,925

(22) Filed: Jul. 2, 2018

(51) Int. Cl. G01R 1/04

(52) U.S. Cl. CPC G01R 1/0466

(57) ABSTRACT

A testing socket including a circuit board having a by-pass circuit and testing pins is provided. The circuit board includes a core dielectric layer, a power plane, and a ground plane. The core dielectric layer has a first surface and a second surface opposite to the first surface. The power plane is located on the first surface of the core dielectric layer, and the power plane is electrically connected to the by-pass circuit. The ground plane is located on the second surface of the core dielectric layer. The testing pins penetrates the circuit board, wherein two ends of each the testing pins are protruding out of the circuit board, a first group of the testing pins are electrically connected to the power plane, and a second group of the testing pins are electrically isolated from the power plane.

### BACKGROUND OF THE INVENTION

### 1. Field of the Invention

The disclosure generally relates to a testing socket and a testing apparatus having the testing socket, and more particularly, to a testing socket and a testing apparatus having the testing socket for semiconductor packages and/or semiconductor devices.

### 2. Description of Related Art

In recently years, electronic products are more important for human's life. In order for the electronic products to achieve being light, slim, short, and small, semiconductor packaging technology has kept progressing, in attempt to develop products that are smaller in volume, lighter in weight, higher in integration, and more competitive in market. As such, to maintaining a given product performance of the electronic products, the operation frequency of semiconductor packages continuously increases while miniaturizing the semiconductor packages and increasing the data transmission speed thereof, which testing the high frequency semiconductor packages in the electronic products has become a challenge to researchers in the field.

### SUMMARY OF THE INVENTION

The disclosure provides a testing socket and a testing apparatus having the testing socket, which is able to provide better testing efficiency by suppressed noise generated in signal testing of electronic products.

The disclosure provides a testing socket including a circuit board having a by-pass circuit and testing pins. The circuit board includes a core dielectric layer, a power plane, and a ground plane. The core dielectric layer has a first surface and a second surface opposite to the first surface. The power plane is located on the first surface of the core dielectric layer, and the power plane is electrically connected to the by-pass circuit. The ground plane is located on the second surface of the core dielectric layer. The testing pins penetrates the circuit board, wherein two ends of each the testing pins are protruding out of the circuit board, a first group of the testing pins are electrically connected to the power plane, and a second group of the testing pins are electrically isolated from the power plane.

The disclosure provides a testing apparatus including a testing socket and a control board is provided. The testing socket includes a circuit board, at least one first testing pin, and at least one second testing pin. The circuit board includes a core dielectric layer, a power plane, a capacitor, a capacitor, and a ground plane. The core dielectric layer has a first surface and a second surface opposite to the first surface. The power plane is located on the first surface of the core dielectric layer. The capacitor is embedded in the circuit board and electrically connected to the power plane. The ground plane is located on the second surface of the core dielectric layer. The at least one first testing pin and the at least one second testing pin penetrate the circuit board and protrude out of the circuit board, wherein the at least one first testing pin is electrically connected to the power plane. The control board includes a signal processor, wherein the control board is electrically connected to the testing socket through the at least one first testing pin and the at least one second testing pin.

Based on the above, the testing socket includes a circuit board having a by-pass circuit which is able to suppress the noise generated in signal testing of electronic products, thus the testing efficiency is enhanced and the testing power integration is achieved. Moreover, the testing pins of the testing socket ensure the electrical connection between the control board and electronic products to be tested by a proper physical connection which prevents the electronic products to be tested from being damaged.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic three-dimensional side-view diagram of a testing socket according to an embodiment of the disclosure.

FIG. 2A to FIG. 2D are schematic cross-sectional views illustrating a manufacturing method of a testing socket according to an embodiment of the disclosure.

FIG. 3 is a schematic cross-sectional view of a testing pin according to an embodiment of the disclosure.

FIG. 4 is a schematic cross-sectional view of a testing socket according to another embodiment of the disclosure.

FIG. 5 is a schematic cross-sectional view of a testing apparatus according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts. It is noted that, in accordance with the standard practice in the industry, various features are not drawn to scale. In fact, the dimensions of the various features may be arbitrarily increased or reduced for clarity of discussion.

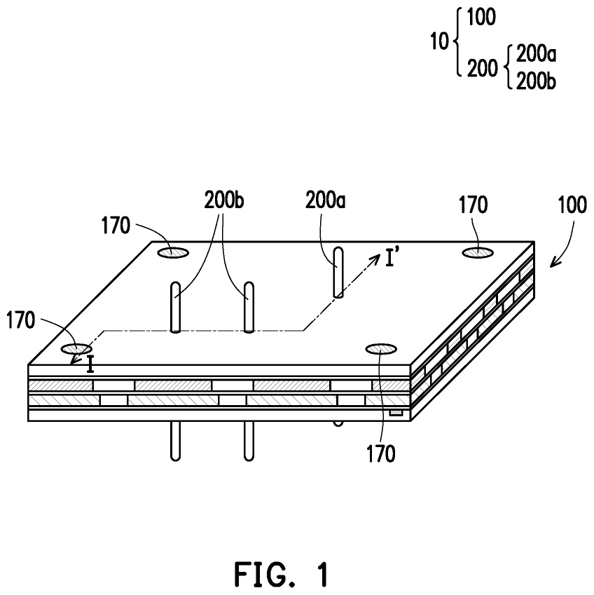

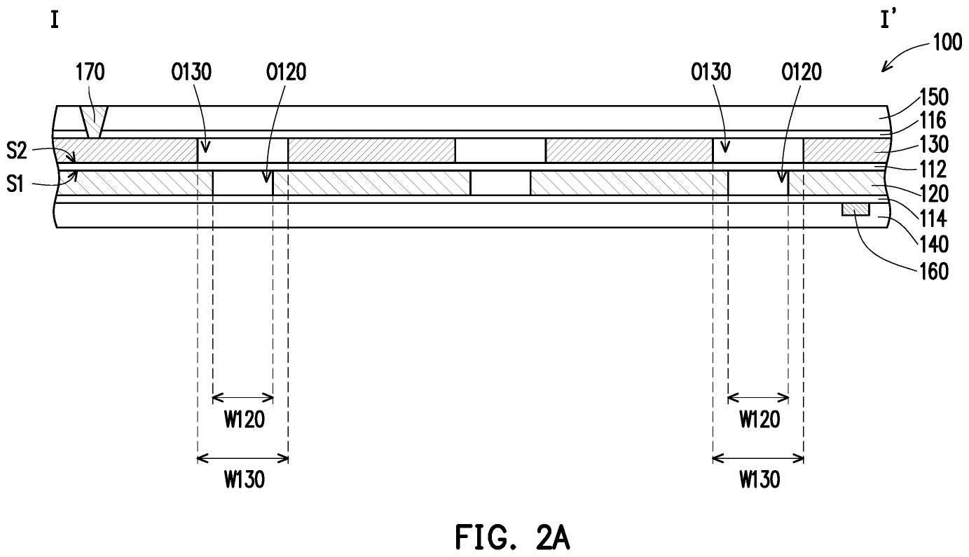

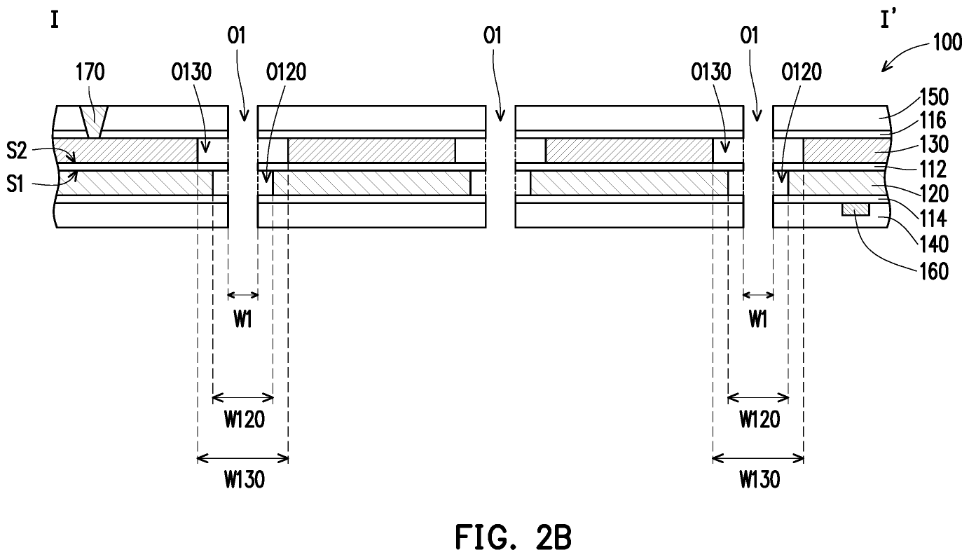

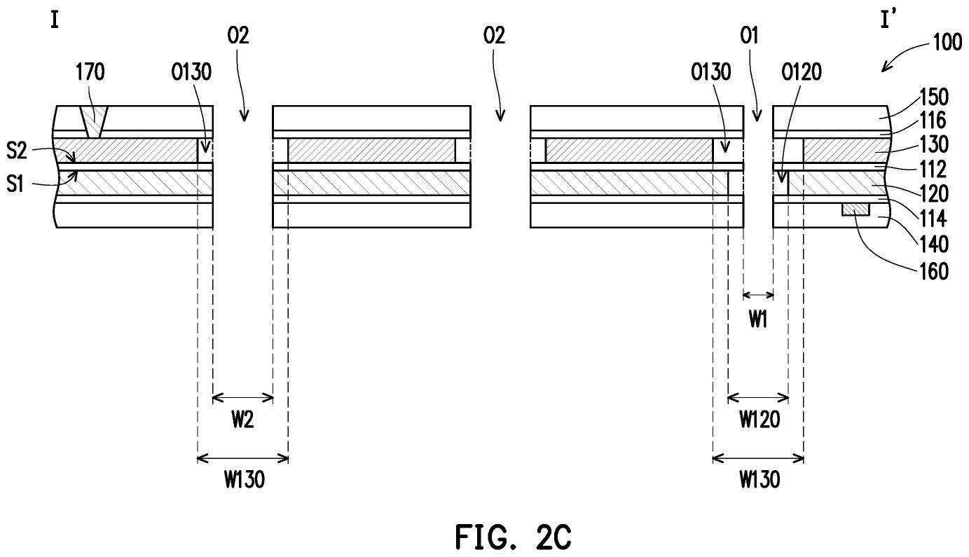

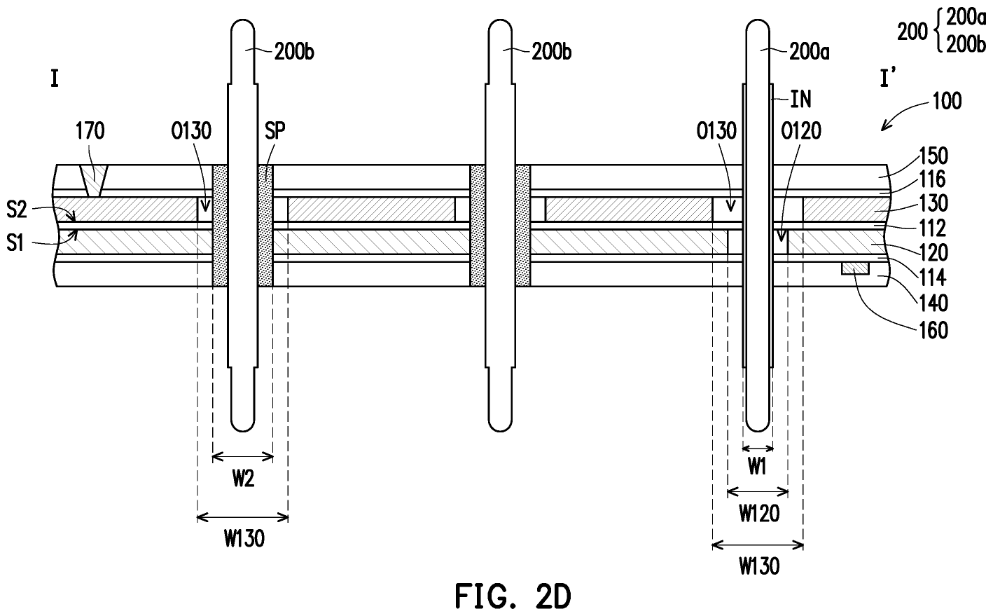

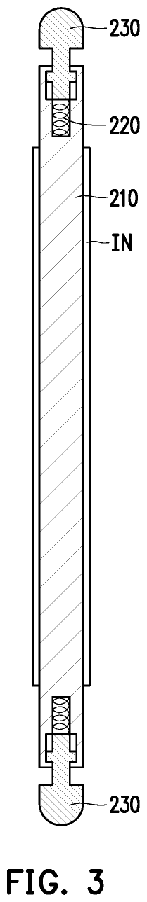

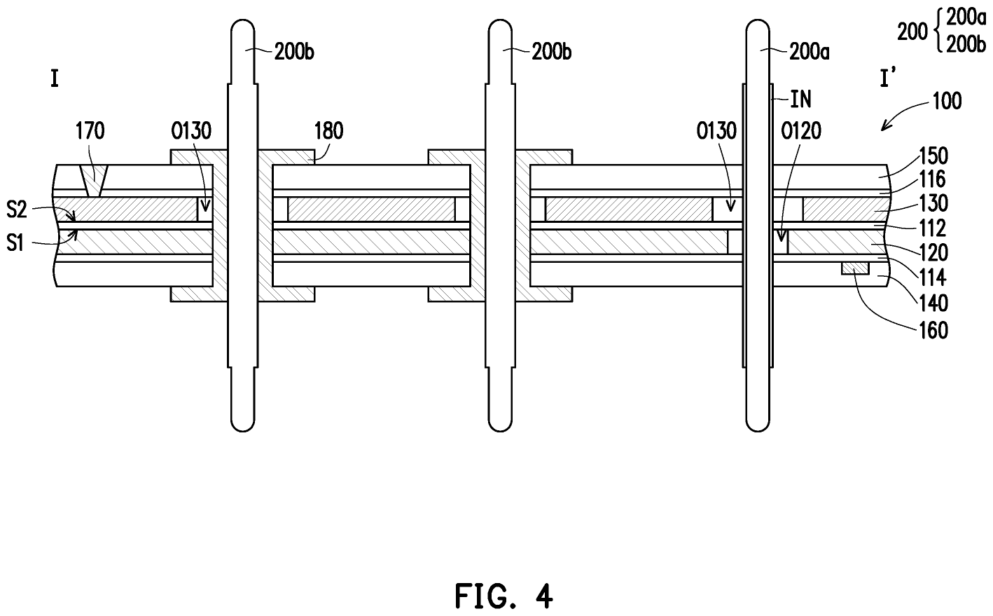

FIG. 1 is a schematic three-dimensional side-view diagram of a testing socket according to an embodiment of the disclosure. FIG. 2A to FIG. 2D are schematic cross-sectional views illustrating a manufacturing method of a testing socket according to an embodiment of the disclosure, where FIG. 2A to FIG. 2D are the schematic cross-sectional views taken along a line I-I′ depicted in FIG. 1. FIG. 3 is a schematic cross-sectional view of a testing pin according to an embodiment of the disclosure, and FIG. 3 is the schematic cross-sectional view of the testing pins depicted in FIG. 2D. FIG. 4 is a schematic cross-sectional view of a testing socket according to another embodiment of the disclosure. The embodiments are intended to provide further explanations but are not used to limit the scope of the disclosure.

Referring to FIG. 1 and FIG. 2A, a circuit board 100 is provided, and the circuit board 100 includes a dielectric layer 112, a dielectric layer 114, a dielectric layer 116, a power plane 120, a ground plane 130, a solder mask layer 140, a solder mask layer 150, a by-pass circuit 160, and conductive vias 170.

For example, the circuit board 100 may include one or more dielectric layers (e.g. a dielectric layer 112, a dielectric layer 114, a dielectric layer 116, a solder mask layer 140 and a solder mask layer 150) and one or more patterned conductive layers (e.g. a power plane 120 and a ground plane 130) arranged in alternation. The number of the dielectric layers and the number of the patterned conductive layers may be designated based on the design layout, and is not limited to the disclosure. In some embodiments, the power plane 120 is disposed on a first surface S1 of the dielectric layer 112. The dielectric layer 114 and the solder mask layer 140 may be disposed on the power plane 120. In some embodiments, the ground plane 130 is disposed on a second surface S2 of the dielectric layer 112. The dielectric layer 116 and the solder mask layer 150 may then be disposed on the ground plane 130. The first surface S1 is opposite to the second surface S2. In other words, the dielectric layer 112 is sandwiched between the power plane 120 and the ground plane 130, the dielectric layer 114 is sandwiched between the power plane 120 and the solder mask layer 140, and the dielectric layer 116 is sandwiched between the ground plane 130 and the solder mask layer 150.

For example, materials of the dielectric layer 112, the dielectric layer 114, the dielectric layer 116 may include inorganic or organic dielectric materials such as silicon oxide, silicon nitride, polyimide, benezocyclobutene (BCB), or the like, and may be formed by spin-coating and/or deposition such as chemical vapor deposition (CVD) or the like. For example, materials of the power plane 120 and the ground plane 140 may include a conductive material, such as copper, aluminium, or nickel, may be formed by a sputtering process, an evaporation process, or an electroplating process. In some embodiments, the materials and the formation methods of the dielectric layer 112, the dielectric layer 114, the dielectric layer 116 may be the same. The materials of the power plane 120 and the ground plane 130 may be the same. However, the disclosure is not limited thereto. In some embodiments, as shown in FIG. 2A, the dielectric layer 112 is located between the power plane 120 and the ground plane 130. The power plane 120 is located between the dielectric layer 112 and the dielectric layer 114. The ground plane 130 is located between the dielectric layer 112 and the dielectric layer 116. The dielectric layer 114 is located between the power plane 120 and the solder mask layer 140. And, the dielectric layer 116 is located between the ground plane 130 and the solder mask layer 150.

In some embodiments, as shown in FIG. 2A, the power plane 120 has a plurality of through holes O120, and the ground plane 130 has a plurality of through holes O130. One of the through holes O120 formed in the power plane 120 is concentric to a respective through hole O130 formed in the ground plane 130. For example, the power plane 120 may be a patterned conductive layer including at least one through hole, and the ground plane 130 may be a patterned conductive layer including at least one through hole. The patterned conductive layers may be formed by performing lithography and etching processes to form the through holes. However, the disclosure is not limited thereto.

Continued on FIG. 2A, in some embodiments, a width W120 of one through hole O120 formed in the power plane 120 is less than a width W130 of a corresponding through hole O130 formed in the ground plane 130. For example, the width W120 may range from about 0.10 mm to about 0.50 mm. For example, the width W130 may range from about 0.25 mm to about 0.68 mm. In some embodiments, along a layer-stacking direction of the power plane 120 and the ground plane 130 (e.g. a vertical direction), sidewalls of the through holes O120 is not aligned with sidewalls of the through holes O130, so that there is an offset between the sidewall of one through hole O120 and the sidewall of a corresponding through hole O130.

In some embodiments, the by-pass circuit 160 is electrically connected to the power plane 120. For example, the by-pass circuit 160 may be a capacitor such as a by-pass capacitor embedded in the circuit board 100, as shown in FIG. 2A. However, the disclosure is not limited thereto. In some alternative embodiments, the by-pass circuit 160 may be a capacitor structure formed using a portion of the power plane 120, a pattern portion of the ground plane 130, or a portion of the power plane 120 and a portion of the ground plane 130 combined. In the embodiment of which the capacitor structure includes the portion of the ground plane 130, such portion of the ground plane 130 is electrically isolated from the rest of the ground plane 130.

In some embodiments, the conductive vias 170 are electrically connected to the ground plane 140. For example, the conductive vias 170 may be formed by patterning the solder mask layer 150 and the dielectric layer 116 to form openings exposing portions of the ground plane 130. The openings are then filled up with a conductive material to form the conductive vias 170 in the solder mask layer 150 and the dielectric layer 116. The conductive material for forming the conductive vias 170 may include copper, aluminium, or nickel. The conductive vias 170 may be formed by a sputtering process, an evaporation process, or an electroplating process. The patterning process may include lithography and etching processes. In FIG. 1, four conductive vias 170 are shown for illustration purpose, and is not used to limited the scope of the disclosure. In some embodiments, the number of the conductive vias 170 may be selected based on the demand, and the disclosure is not limited thereto.

In some embodiments, as shown in FIG. 2A, the conductive vias 170 are formed in the solder mask layer 150 and the dielectric layer 116. The conductive vias 170 may be physically connected to the ground plane 130. For example, as shown in FIG. 1, the conductive vias 170 are respectively disposed on the corners of the circuit board 100. The positioning configuration of the conductive vias 170 allows a balance in the electrical potential of the ground plane 130 to be obtained.

Referring to FIG. 2B, a first patterning process is performed on the circuit board 100 to form through holes O1. The through holes O1 may penetrate the circuit board 100. The first patterning process may include a laser drill process or a mechanical drill process, but the disclosure is not limited thereto. As shown in FIG. 2B, the through holes O1 are forming to penetrate the circuit board 100. The through holes O1 may pass through some of the through holes O120 and the through holes O130 corresponding to the through holes O120. In some embodiments, a width W1 of one through hole O1 is less than the width W120 of a corresponding through hole O120 and the width W130 of a corresponding through hole O130. In some embodiments, along the layer-stacking direction of the power plane 120 and the ground plane 130, sidewalls of the through holes O1 are not aligned with the sidewalls of the through holes O120 and the sidewalls of the through holes O130. For example, an offset is between the sidewall of one through hole O1 and the sidewall of a corresponding through hole O120. Similarly, an offset is between the sidewall of one through hole O1 and the sidewall of a corresponding through hole O130. In certain embodiments, the through holes O1, the through holes O120, and the through holes O130 are concentric, however the disclosure is not limited thereto.

In some embodiments, in the through holes O1, sidewalls of the power plane 120 and the ground plane 130 are not aligned with sidewalls of the dielectric layer 112, the dielectric layer 114, the dielectric layer 116, the solder mask layer 140, and the solder mask layer 150. As shown in FIG. 2B, in the through holes O1, the sidewalls of the ground plane 130 are not aligned with the sidewalls of the power plane 120. A width of a gap distancing the sidewalls of the power plane 120 from the sidewalls of the through holes O1 is less than a width of a gap distancing the sidewalls of the ground plane 130 from the sidewalls of the through holes O1, in the through holes O1. For example, the above gaps are respectively considered part of the though hole O120 and part of the through holes O130. Further, the gaps may be air-gaps.

Referring to FIG. 2C, a second patterning process is performed on the circuit board 100 to form through holes O2. The through holes O2 may penetrate the circuit board 100. The second patterning process may include a laser drill process or a mechanical drill process, the disclosure is not limited thereto.

For example, in one embodiment, the through holes O2 may be formed to penetrate the circuit board 100 and pass through the through holes O1. The number of the through holes O2 is less than the number of the through holes O1. In such embodiment, the circuit board 100 has the through holes O1 and the through holes O2 simultaneously. However, the disclosure is not limited thereto. In some embodiments, the number of the through holes O2 may be greater than or equal to the number of the through holes O1, then the circuit board 100 may have the through holes O2 only.

In an alternative embodiment, the through holes O2 may be formed to penetrate the circuit board 100 and pass through some of the through holes O120 and the corresponding through holes O130. The through holes O2 do not pass through the through holes O1. In such embodiment, the circuit board 100 has the through holes O1 and the through holes O2 simultaneously.

In a further alternative embodiment, the through holes O2 may be formed to penetrate the circuit board 100 and pass through some of the through holes O1 and some of the through holes O120 and the respective through holes O130. In such embodiment, the circuit board 100 has the through holes O1 and the through holes O2 simultaneously. The disclosure does not limit the forming manner of the through holes O2.

After the second patterning process, the circuit board 100 may include one or more than one through holes O1 and one or more than one through holes O2, however the disclosure is not limited thereto. For easy illustration, only one through hole O1 and two through holes O2 are shown in the circuit board 100 depicted in FIGS. 2C and 2D, however the disclosure is not limited thereto. The numbers of the through holes O1 and O2 may be selected based on the demand and the design layout.

In some embodiments, a width W2 of one through hole O2 is greater than the width W1 of a corresponding through hole O1 and the width W120 of a corresponding through hole O120, but is less than the width W130 of a corresponding through hole O130, as shown in FIG. 2C. In other words, one through hole O1 and a corresponding through hole O120 originally located in the location of one through hole O2 are completely removed due to the formation of such through hole O2. In some embodiments, along the layer-stacking direction where the power plane 120 is stacked on the ground plane 130, sidewalls of the through holes O2 are not aligned with the sidewalls of the through holes O130. An offset is formed between the sidewall of one through hole O2 and the sidewall of a corresponding through holes O130. In some embodiments, the through holes O2 and the through holes O130 are concentric, however the disclosure is not limited thereto.

In some embodiments, in the through holes O2, the sidewalls of the power plane 120 are aligned with the sidewalls of the dielectric layer 112, the dielectric layer 114, the dielectric layer 116, the solder mask layer 140, and the solder mask layer 150. In the through holes O2, the sidewalls of the ground plane 130 are not aligned with and are distant from the sidewalls of the dielectric layer 112, the dielectric layer 114, the dielectric layer 116, the power plane 120, the solder mask layer 140, and the solder mask layer 150. For example, as shown in FIG. 2C, in the through holes O2, the sidewalls of the ground plane 130 are not aligned with the sidewalls of the dielectric layer 112, the dielectric layer 114, the dielectric layer 116, the power plane 120, the solder mask layer 140, and the solder mask layer 150, and the sidewalls of the ground plane 130 is distant from the sidewalls of the through holes O2 by gaps. For example, the above gaps are considered part of the through holes O130. Further, the gaps may be air-gaps.

Referring to FIG. 2D, one or more testing pins 200 are provided. In some embodiments, the testing pins 200 are inserted into the through holes O1 and O2 formed in the circuit board 100, respectively. As shown in FIG. 2D, the testing pins 200 includes one or more first testing pins 200a and one or more second testing pins 200b. For illustration purpose, one first testing pin 200a and two second testing pins 200b are shown in FIG. 2D, and the disclosure is not limited thereto. In some embodiments, based on the demand, the number of the first testing pins 200a can be more than one, and the number of the second testing pins 200b can be less than two or more than two.

Referring to FIG. 2D, the first testing pin 200a is respectively inserted into the through hole O1, and is electrically isolated from the power plane 120 and the ground plane 130 through an insulator IN. In one embodiment, the first testing pin 200a serves as a ground testing pin or a signal testing pin, and may be a pogo pin. For example, the first testing pin 200a includes a body portion 210, elastic elements 220 and moving portions 230, as shown in FIG. 3. The body portion 210 has two end portions each having a hollow structure for accommodating one of the elastic elements 220 and one of the moving portions 230. As shown in FIG. 3, the elastic elements 220 each are completely located inside the hollow structure of each of the end portions. A portion of each of the moving portions 230 is located inside the hollow structure of each of the end portions, and the other portion of each of the moving portions 230 (e.g. opposite to the portion located inside the hollow structure) is protruding out of the body portion 210 for contacting external elements (e.g. an object to be tested or a control board providing testing signals and power source). For example, materials of the body portion 210, the elastic elements 220, and the moving portions 230 may include conductive materials, such as metal or metal alloy. For example, the elastic elements 220 may be springs, coils, or the like. Owing to the elastic elements 220, the moving portions 230 are able to move upward or downward inside the hollow structures of the body portion 210, thereby providing the first testing pins 200a with elasticity against an external pressure. As shown in FIG. 3, the body portion 210, the elastic elements 220 and the moving portions 230 are electrically connected to each other by physically connecting the elastic elements 220 with the body portion 210 and the moving portions 230.

In one embodiment, the insulator IN may be formed on the first testing pin 200a. In certain embodiments, the insulator IN is formed on the body portion 210 of the first testing pin 200a, as shown in FIG. 3. For example, a material of the insulator IN may include inorganic or organic dielectric materials such as silicon oxide, silicon nitride, polyimide, BCB or the like, and may be formed by spin-coating and/or deposition such as CVD or the like. However, the disclosure is not limited thereto.

In an alternative embodiment, the insulator IN may be formed on the sidewall of the through hole O1. For example, the insulator IN may be formed by forming a blanket layer of insulating material covering the solder mask layer 140, the solder mask layer 150 and the sidewall of the through hole O1, and then patterning the insulating material blanket layer to form the insulator on the sidewall of the through hole O1. The formation method of the insulating material blanket layer may be a spin-coating process and/or a deposition process, and the patterning process may be lithography and etching processes.

As shown in FIG. 2D, in the through hole O1, the insulator IN is sandwiched between the circuit board 100 and the first testing pin 200a. For example, the insulator IN at least wraps a portion of the sidewall of the first testing pin 200a inserted in the through hole O1. In some embodiments, in the portion of the circuit board 100 where one through hole O1 formed therein, the insulator IN is located between one through hole O120 and the first testing pin 200a and between one through hole O130 and the first testing pin 200a. The insulator IN is distant from the sidewalls of the power plane 120 and the ground plane 130, and the first testing pin 200a is electrically isolated from the power plane 120 and the ground plane 130. The first testing pin 200a is inserted in the through hole O1, and two terminals of the first testing pin 200a protrude out of the circuit board 100 for contacting external elements (e.g. an object to be tested or a control board providing testing signals and power source for electrically grounded).

Continued on FIG. 2D, the second testing pins 200b are respectively inserted into the through holes O2, and are electrically connected to the power plane 120. In one embodiment, the second testing pins 200b serve as power testing pins, and may be pogo pins. The structure and material of the second testing pins 200b is the same as the structure and material of the first testing pin 200a described in FIG. 3, and thus will not be repeated herein. The difference between one first testing pin 200a and one second testing pin 200b is that, for example but not limited to, there is no insulator on the sidewall of each second testing pin 200b.

In some embodiments, the second testing pins 200b are electrically connected to the power plane 120 through conductive elements, respectively. The conductive elements may be silver pastes SP, as shown in FIG. 2D. For example, the silver pastes SP may be formed onto an outer surface of the solder mask layer 140 about at the location of the through holes O2, and the second testing pins 200b may be inserted into the through holes O2 along a direction from the solder mask layer 140 to the solder mask layer 150. Along with the movement of the second testing pins 200b in the insertion, the silver pastes SP may correspondingly flow into the through holes O2. The silver pastes SP remained on the outer surface of the solder mask layer 140 may be removed. The silver pastes SP may be formed by dispensing, for example. In some embodiments, in one through hole O2, a corresponding silver paste SP is sandwiched between the circuit board 100 and the second testing pin 200b. As shown in FIG. 2D, in one through hole O2, the silver paste SP wraps a portion of the sidewall of a respective second testing pin 200b inserted in the through hole O2. The second testing pins 200b are electrically connected to the power plane 200 since the silver pastes SP are sandwiched between and physically contact to the second testing pins 200b and the power plane 120. The silver pastes SP are distant from the sidewalls of the ground plane 130, and the second testing pins 200b are electrically isolated from the ground plane 130. As shown in FIG. 2D, the second testing pins 200b are respectively inserted in the through holes O2, and two terminals of each of the second testing pins 200b protrude out of the circuit board 100 for contacting external elements (e.g. an object to be tested or a control board providing power). Up to this, the testing socket 10 of the disclosure is manufactured.

However, the disclosure is not limited thereto. In other alternative embodiments, each of the second testing pins 200b may be electrically connected to the power plane 120 through a conductive film 180, as shown in FIG. 4. For example, a material of the conductive film 180 may be copper, aluminium, or nickel. For example, a blanket layer of conductive material is formed to cover the solder mask layer 140, the solder mask layer 150 and the sidewalls of the through holes O2, and then the conductive material blanket layer is patterned to form one or more than one conductive films 180. The formation method of the conductive material blanket layer may be a sputtering process, an evaporation process, or an electroplating process, and the patterning process may be lithography and etching processes. In one embodiment, in one through hole O2, the conductive film 180 is sandwiched between the circuit board 100 and a respective second testing pin 200b. As shown in FIG. 4, each conductive film 180 covers the sidewall of a corresponding through hole O2 and extends to a portion of the outer surface of the solder mask layer 140 and a portion of an outer surface of the solder mask layer 150. In some embodiments, in each of the through holes O2, the conductive film 180 wraps a portion of the sidewall of the second testing pin 200b inserted in the corresponding through hole O2. Each of the second testing pins 200b is electrically connected to the power plane 200 since the corresponding conductive film 180 is sandwiched between and physically contacts one second testing pin 200b and the power plane 120. As shown in FIG. 4, the conductive film 180 is distant from the sidewalls of the ground plane 130, and the second testing pins 200b are electrically isolated from the ground plane 130.

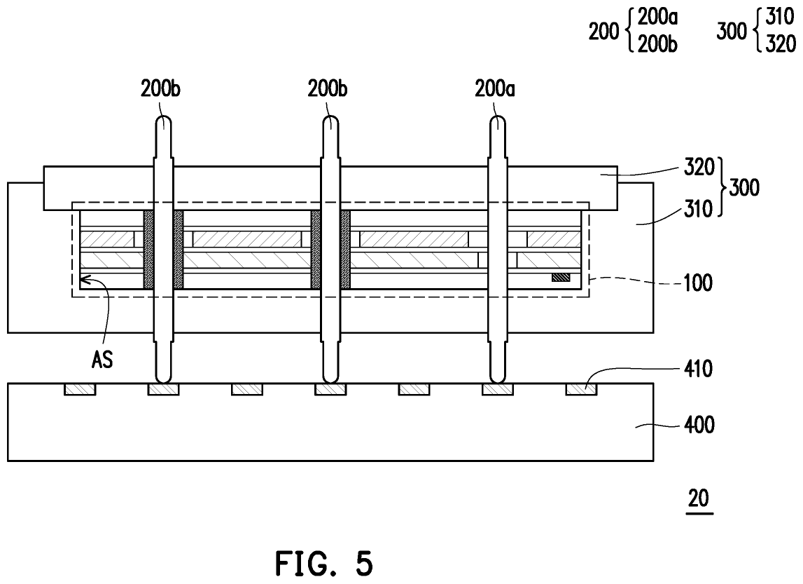

Referring to FIG. 5, a testing apparatus 20 includes a testing socket 10 having a circuit board 100 and testing pins 200 penetrating therethrough, a housing 300, and a control board 400. In some embodiments, for the testing socket 10, the circuit board 100 and the testing pins 200 (including first testing pin 200a and the second testing pins 200b) may include the structures depicted in FIG. 2D and FIG. 3 or the structures depicted in FIG. 3 and FIG. 4; certain details or descriptions of the circuit board 100 and the testing pins 200 and the relationship thereof (e.g. the relative positioning configuration and electrical connection) will not be repeated herein.

In some embodiments, the testing socket 10 is placed into the housing 300, and the two terminals of each of the first testing pin 200a and the second testing pins 200b are protruded out the housing 300, as shown in FIG. 5. For example, the housing 300 includes a body 310 and a cover 320, and the circuit board 100 are disposed inside an accommodating space defined by the body 310 and the cover 320. The body 310 has a plurality of first openings and the cover 320 has a plurality of second openings. The locations of the second openings in the cover 320 are corresponding to the locations of the first openings in the body 310. As shown in FIG. 5, the two terminals of each of the first testing pin 200a and the second testing pins 200b are protruded out the housing 300 through one first opening and a corresponding second opening, respectively. For example, materials of the body 310 and the cover 320 of the housing 300 may include insulating material.

In some embodiments, the terminals of the first testing pin 200a and the second testing pins 200b penetrating through the first openings formed in the body 310 may be electrically connected to the control board 400. For example, the control board 400 may be a circuit structure board, and may include contacts 410 for connecting external elements, metal segments for electric circuit layout, and signal process for signal testing and processing. The control board 410 is able to provide testing patterns (e.g. electric testing signals) or the power source (for power or electrically grounded) to the testing pins 200, depending the types of the testing pins 200. As shown in FIG. 5, the terminals of the first testing pin 200a and the second testing pins 200b protruded out the first openings formed in the body 310 may be electrically connected to the contacts 410 of the control board 400.

On the other hand, the other terminals of the first testing pin 200a and the second testing pins 200b penetrating through the second openings formed in the cover 320 may be electrically connected to an object to be tested (e.g. a semiconductor package). For example, the other terminals of the first testing pin 200a and the second testing pins 200b protruded out the second openings formed in the cover 320 may be contacted to connectors (e.g. solder balls or ball grid array (BGA) balls, chip connectors (“C4”) or the like) of the semiconductor package.

With such configuration of the testing apparatus 20, the testing signal provided by the control board 400 is transmitted to the objected to be tested (e.g. the semiconductor package) through the first testing pin 200a of the testing pins 200a. And, through the first testing pin 200a, a feedback is transmitted back from the object to be tested to the control board 400 for further processing (e.g. determining the semiconductor package's performance) by the signal processor. A power is provided to the circuit board 100 embedded with the by-pass circuit through the second testing pins 200b of the testing pins 200 from the control board 400 so that the noise generated in signal testing is suppressed.

Based on the above, the testing socket includes a circuit board having a by-pass circuit which is able to suppress the noise generated in signal testing of electronic products, thus the testing efficiency is enhanced and the testing power integration is achieved. Moreover, the testing pins of the testing socket ensure the electrical connection between the control board and electronic products to be tested by a proper physical connection which prevents the electronic products to be tested from being damaged.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A testing socket, comprising:
a circuit board having a by-pass circuit, the circuit board comprising:
a core dielectric layer, having a first surface and a second surface opposite to the first surface;
a power plane, located on the first surface of the core dielectric layer, the power plane being electrically connected to the by-pass circuit; and
a ground plane, located on the second surface of the core dielectric layer; and
testing pins, penetrating the circuit board, wherein two ends of each the testing pins are protruding out of the circuit board, a first group of the testing pins are electrically connected to the power plane, and a second group of the testing pins are electrically isolated from the power plane.

2. The testing socket of claim 1, wherein the power plane comprises at least one first through hole, the ground plane comprises at least one second through hole, the at least one first through hole and the at least one second through hole are concentric, and a diameter of the at least one first through hole is less than a diameter of the at least one second through hole.

3. The testing socket of claim 2, wherein the testing pins penetrate the circuit board through the at least one first through hole and the least one second through hole.

4. The testing socket of claim 3, further comprising:
a conductive material, located between and electrically connected the first group of the testing pins and the power plane.

5. The testing socket of claim 3, wherein a gap is located between and electrically isolated the first group of the testing pins and the ground plane.

6. The testing socket of claim 3, further comprising:
insulators, located between and electrically isolated the second group of the testing pins and the power plane, and located between and electrically isolated the second group of the testing pins and the ground plane.

7. The testing socket of claim 1, wherein the first group of the testing pins comprise power testing pins, and the second group of the testing pins comprise ground testing pins and/or signal testing pins.

8. The testing socket of claim 1, further comprising:
a first dielectric layer, located over the first surface of the core dielectric to cover the power plane; and
a second dielectric layer, located over the second surface of the core dielectric to cover the ground plane.

9. The testing socket of claim 8, further comprising:
a plurality of conductive vias, located in the second dielectric layer and electrically connected to the ground plane, wherein the conductive vias are physically separated and spaced apart from each other along an edge of the circuit board.

10. The testing socket of claim 8, further comprising a housing having a plurality of openings and an accommodating space, wherein the testing pins pass through the openings, and the circuit board is disposed in the accommodating space of the housing.

11. A testing apparatus, comprising:
a testing socket, comprising:
a circuit board, comprising:
a core dielectric layer, having a first surface and a second surface opposite to the first surface;
a power plane, located on the first surface of the core dielectric layer;
a capacitor, embedded in the circuit board and electrically connected to the power plane; and
a ground plane, located on the second surface of the core dielectric layer; and
at least one first testing pin and at least one second testing pin, penetrating the circuit board and protruding out of the circuit board, wherein the at least one first testing pin is electrically connected to the power plane; and
a control board comprising a signal processor, electrically connected to the testing socket through the at least one first testing pin and the at least one second testing pin.

12. The testing apparatus of claim 11, wherein the power plane comprises at least one first through hole, the ground plane comprises at least one second through hole, the at least one first through hole and the at least one second through hole are concentric, and a diameter of the at least one first through hole is less than a diameter of the at least one second through hole.

13. The testing apparatus of claim 12, wherein the at least one first testing pin and the at least one second testing pin penetrate the circuit board through the at least one first through hole and the least one second through hole.

14. The testing apparatus of claim 13, further comprising:
a conductive material, located between and electrically connected the at least one first testing pin and the power plane.

15. The testing apparatus of claim 13, wherein a gap is located between and electrically isolated the at least one first testing pin and the ground plane.

16. The testing apparatus of claim 11, wherein the at least one first testing pin comprises at least one power pogo-pin, and the at least one first testing pin is electrically isolated from the ground plane.

17. The testing apparatus of claim 11, wherein the at least one second testing pin comprises at least one ground pogo-pin and/or at least one signal pogo-pin, and the at least one second testing pin is electrically isolated from the power plane.

18. The testing apparatus of claim 11, further comprising:
a first dielectric layer, located over the first surface of the core dielectric layer to cover the power plane; and
a second dielectric layer, located over the second surface of the core dielectric layer to cover the ground plane.

19. The testing apparatus of claim 18, further comprising:
a plurality of conductive vias, located in the second dielectric layer and electrically connected to the ground plane, wherein the conductive vias are physically separated and spaced apart from each other along an edge of the circuit board.

20. The testing apparatus of claim 18, wherein the testing socket further comprises a housing having a plurality of openings and an accommodating space, wherein the at least one first testing pin and the at least one second testing pin pass through the openings, and the circuit board is disposed in the accommodating space of the housing.
